(19) United States
(12) Patent Application Publication
(10) Pub. No.: US 2024/0164099 A1
(43) Pub. Date: May 16, 2024

(54) MEMORY DEVICE AND METHOD FOR FORMING THE SAME

(71) Applicant: MACRONIX INTERNATIONAL CO., LTD., HSINCHU (TW)

(72) Inventors: Hong-Ji LEE, Taoyuan City (TW); Tzung-Ting HAN, Taoyuan City (TW); Chang-Wen JIAN, Taoyuan City (TW)

(21) Appl. No.: 18/184,078

(22) Filed: Mar. 15, 2023

Related U.S. Application Data
(60) Provisional application No. 63/425,683, filed on Nov. 16, 2022.

(51) Int. Cl. H10B 43/27

(52) U.S. Cl. CPC H10B 43/27

(57) ABSTRACT

An integrated circuit structure includes a substrate, semiconductor devices, an inter-layer dielectric (ILD) structure, an interconnect, a dielectric layer, an etching barrier layer, a conductive layer, and memory units. The semiconductor devices are on the substrate. The ILD structure is over the semiconductor devices. The interconnect is in the ILD structure and electrically connected to the semiconductor devices. The dielectric layer is over the ILD structure. The etching barrier layer is on the first dielectric layer. The conductive layer is on the etching barrier layer. The memory units are stacked in a vertical direction over the etching barrier layer.

### CROSS-REFERENCE TO RELATED APPLICATION

This application claims priority to U.S. Provisional Application Ser. No. 63/425,683, filed Nov. 16, 2022, which is herein incorporated by reference in its entirety.

### BACKGROUND

### Field of Invention

The present invention relates to a memory device. More particularly, the present invention relates to a method for forming a memory device.

### Description of Related Art

The present disclosure generally relates to semiconductor devices, and particularly to methods of making a 3-dimensional (3D) memory device.

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### SUMMARY

The disclosure provides an integrated circuit (IC) structure includes a substrate, semiconductor devices, an inter-layer dielectric (ILD) structure, an interconnect, a dielectric layer, an etching barrier layer, a conductive layer, and memory devices. The semiconductor devices are on the substrate. The ILD structure is over the semiconductor devices. The interconnect is in the ILD structure and electrically connected to the semiconductor devices. The dielectric layer is over the ILD structure. The etching barrier layer is on the first dielectric layer. The conductive layer is on the etching barrier layer. The memory units are stacked in a vertical direction over the etching barrier layer.

In some embodiments, the etching barrier layer is made of a different material than the first dielectric layer.

In some embodiments, the etching barrier layer is made of a carbon-containing material.

In some embodiments, the etching barrier layer comprises tungsten, titanium, titanium nitride, or combinations thereof.

In some embodiments, the etching barrier layer is made of metal oxide.

In some embodiments, the etching barrier layer is made of a same material as the conductive layer and has a thicker thickness than the conductive layer.

In some embodiments, the IC structure further includes a second dielectric layer sandwiched between the etching barrier layer and the conductive layer.

In some embodiments, the second dielectric layer is made of a same material as the first dielectric layer and different than the etching barrier layer.

In some embodiments, the second dielectric layer is made of a different material than the first dielectric layer and the etching barrier layer.

In some embodiments, the IC structure further includes a source line extending upwardly from the conductive layer and electrically connected to the memory units, wherein the etching barrier layer further laterally extends between the semiconductor units and the source line.

The disclosure provides a method for forming a memory device. The method includes depositing a first dielectric layer over a plurality of semiconductor device on a substrate; depositing an etching barrier layer on the first dielectric layer; forming a conductive layer on the etching barrier layer; forming a first multi-layered stack on the conductive layer, the first multi-layered stack including first insulating layers stacked in a vertical direction and separated from each other; performing a first etching process on the first multi-layered stack to form at least one first vertical through opening downwardly extending through the first multi-layered stack and the conductive layer, the etching barrier layer serving as an etch stop layer, wherein one of the at least one first vertical through opening has a greater depth in the etching barrier layer than another one of the at least one first vertical through opening; forming a memory layer and a channel layer in the at least one first vertical through opening and in contact with the etching barrier layer; forming a plurality of first gate layers alternately stacked with the first insulating layers in the vertical direction.

In some embodiments, the method further includes after performing a first etching process, forming a second multi-layered stack on the first multi-layered stack, the second multi-layered stack including second insulating layers stacked in the vertical direction and separated from each other; performing a second etching process on the second multi-layered stack to form at least one second vertical through opening downwardly extending through the second multi-layered stack and overlapping the at least one first vertical through opening, wherein the memory layer and the channel layer further form in the at least one second vertical through opening.

In some embodiments, the method further includes forming a plurality of second gate layers alternately stacked with the second insulating layers in the vertical direction.

In some embodiments, a ratio of an etching rate of the conductive layer to an etching rate of the etching barrier layer is greater than about 5 during the performing the first etching process.

In some embodiments, the etching barrier layer comprises aluminum oxide, hafnium oxide, or combinations thereof.

In some embodiments, the first dielectric layer is made of silicon oxide.

In some embodiments, the method further includes forming a second dielectric layer on the etching barrier layer prior to forming the conductive layer.

In some embodiments, the second dielectric layer is made of silicon oxide or silicon nitride.

In some embodiments, the etching barrier layer is made of a metal-containing material.

In some embodiments, the etching barrier layer is made of a carbon-containing material.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1A illustrates a cross-sectional view of an integrated circuit (IC) structure according to some embodiments of the present disclosure.

FIG. 1B illustrates a local enlarged view of the IC structure corresponding to the region Cl in FIG. 1A.

FIG. 1C illustrates a local enlarged view of an IC structure corresponding to FIG. 1B according to some embodiments of the present disclosure.

FIGS. 2A, 3-9A, and 10-17A are cross-sectional views illustrating a method in various stages of forming an IC structure in accordance with some embodiments of the present disclosure.

FIG. 2B illustrates a cross-sectional view of an IC structure corresponding to FIG. 2A according to some embodiments of the present disclosure.

FIGS. 9B and 17B illustrate local enlarged views of the IC structure according to the region Cl in FIGS. 9A and 17A, respectively.

FIGS. 9C and 17C illustrate local enlarged views of IC structures corresponding to FIGS. 9B and 17B, respectively, according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

For next generation semiconductor devices, it is desirable to include memories that can provide high density storage. Therefore, a 3-dimensional (3D) integrated circuit (IC) memory device, such as 3D NAND can provide high density storage by its multi-layered structure, in which complementary metal oxide semiconductors (CMOS) can be disposed under the memory array (CuA). However, a hole etch process performed to form a vertical channel hole where a vertical channel formation of the memory device will be formed therein would punch through the underlying interface film on the interconnect connected to the underlying CMOS, such that an abnormal connection (e.g. short circuit) may form between the memory array (e.g. word line in the memory array) and the interconnect (e.g., wiring metal lines) on the CMOS, which in turn adversely affects the performance of the IC structure. Therefore, the present disclosure in various embodiments provides an etching barrier layer inserting between the memory array and MOS in 3D NAND CuA architecture. The etching barrier layer can act as an etch stop layer or an etch buffer layer during the hole etch process, and thus an unwanted abnormal connection in the IC structure can be avoided.

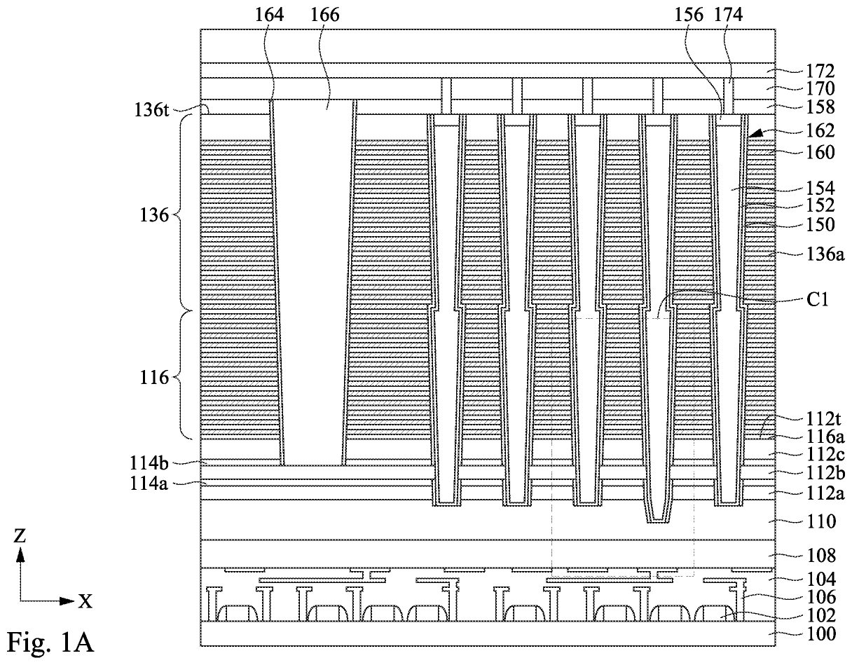

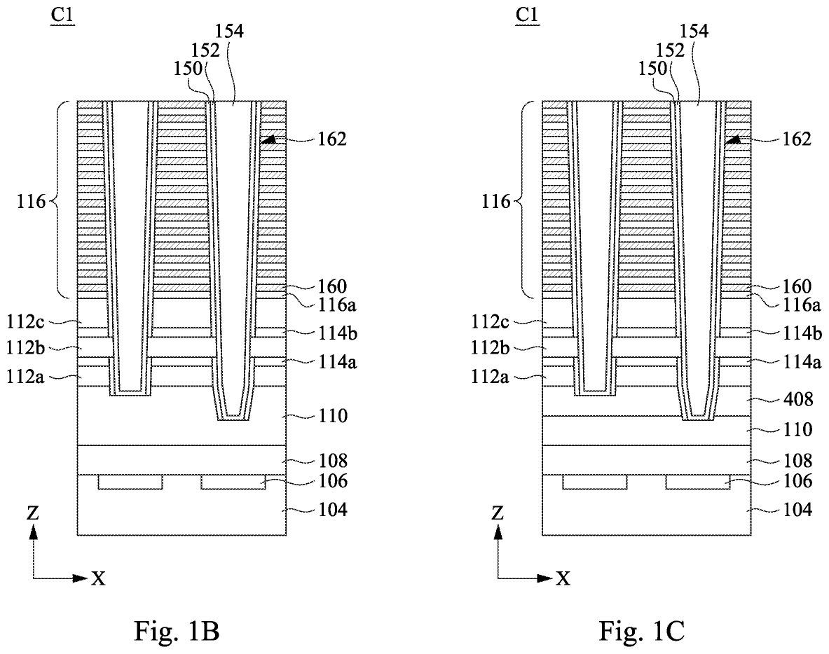

Reference is made to FIGS. 1A and 1B. FIG. 1A illustrates a cross-sectional view of an integrated circuit (IC) structure according to some embodiments of the present disclosure. FIG. 1B illustrates a local enlarged view of the IC structure according to a region Cl in FIG. 1A. As shown in FIG. 1A, complementary metal oxide semiconductors (CMOS) are formed on a substrate 100. The substrate 100 can be a semiconductor substrate, and the CMOS 102 may include PMOS and/or NMOS. An inter-layer dielectric (ILD) layer 104 is formed on the CMOS 102. An interconnect 106 is formed in the ILD 104 and is electrically connected to subsequent formed source lines (SL). In particular, the interconnect 106 is formed at the NMOS/PMOS terminal to connect to the subsequent overlying source lines. Although one ILD layer 104 is shown in the figure, it should be understood that in order to match the connection of the remaining circuits, the number of layers of the ILD layer 104 and the interconnect 106 may be a plurality. In some embodiments, the ILD layer 104 can be interchangeably referred to an ILD structure. A dielectric layer 108 is formed on the ILD layer 104 and the interconnect 106.

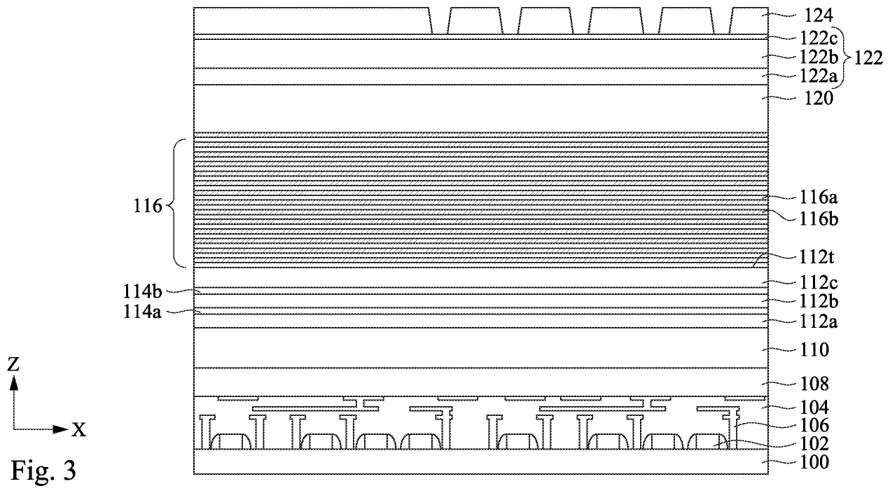

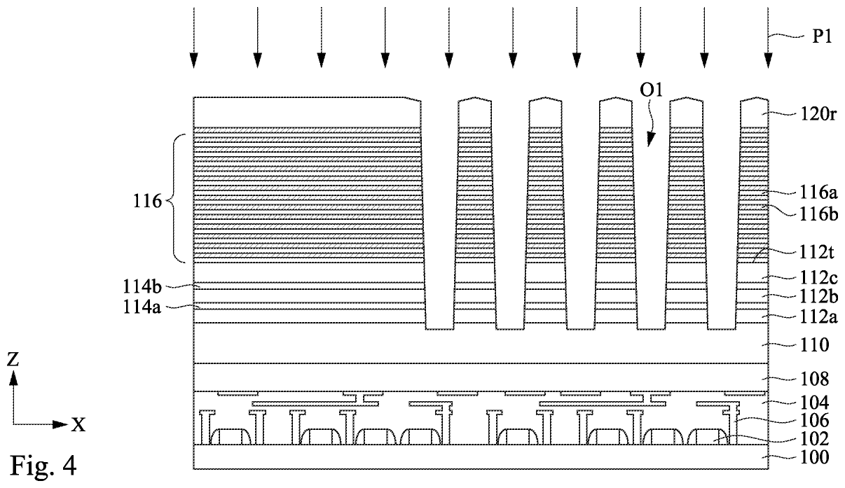

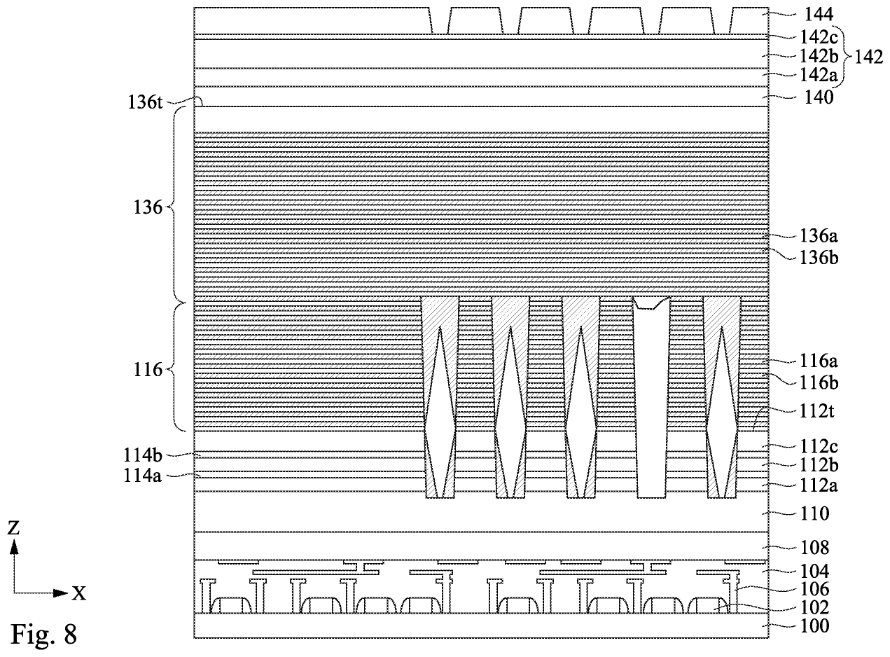

As shown in FIGS. 1A and 1B, an etching barrier layer 110 is formed on the dielectric layer 108 and made of a different material than the underlying dielectric layer 108, such that the etching barrier layer 110 can act as an etch stop layer or an etch buffer layer during a hole etch process (see FIG. 4), and thus a consumption in the underlying interconnect 106 can be avoided, in which the hole etch process is performed to form a vertical channel hole where a vertical channel formation (see FIG. 8) will be formed therein. If the etching barrier layer 110 is not formed between the dielectric layer 108 and the conductive layer 112a (see FIG. 3), the hole etch process (see FIG. 4) would significantly consume the dielectric layer 108 and further consume the underlying interconnect 106, which in turn adversely affects the performance of the IC structure. In some embodiments, a middle sacrificial layer 112b (e.g., polysilicon, silicon nitride, etc.) can be removed by solution and then replaced with highly doped polysilicon to serve as a common source line of the memory devices.

In some embodiments, the etching barrier layer 110 can have a high etch resistance respective to memory array related processes, for example, vertical channel etch, slit trench etch and pillar supporting etching. Once the memory array suffers an unexpectedly punch during the related etching processes, the etching processes would stop on the etching barrier layer 110 and not punch into BEOL CMOS structures, such that a short circuit between the underlying wiring of the CMOS and word line in the memory array can be prevented.

In some embodiments, the etching barrier layer 110 can be made of a same material as an overlying conductive layer 112a and have a thickness thicker than or equal to the overlying conductive layer 112a (see FIG. 3), such that the etching barrier layer 110 can have enough thickness to protect the underlying interconnect 106 and can act as an etch buffer layer during the hole etch process (see FIG. 4), which in turn allowing for avoiding the consumption in the underlying ILD layer 104 and interconnect 106. By way of example but not limiting the present disclosure, the etching barrier layer 110 and the conductive layer 112a can be made of polysilicon, and the etching barrier layer 110 can have a thickness greater than about 1500 angstrom.

In some embodiments, the etching barrier layer 110 may be made of a material that has a high etching selectivity relative to the overlying conductive layer 112a. For example, the etching selectivity, which is the ratio of the etching rate of the conductive layer 112a to the etching barrier layer 110, is greater than about 5 when the conductive layer 112a is etched. In some embodiments, a ratio of the etching rate of the conductive layer 112a to the etching rate of the etching barrier layer 110 may be greater than about 10. If the ratio of the etching I rate of the conductive layer 112a to the etching rate of the etching barrier layer 110 is less than about 5, the hole etch process (see FIG. 4) would significantly consume the etching barrier layer 110, and thus the etching barrier layer 110 after the hole etch process would be too thin to protect the underlying dielectric layer 108 and underlying interconnect 106 in the subsequent process, which in turn adversely affects the performance of the semiconductor device.

By way of example and not limitation, if the conductive layer 112a is made of polysilicon, the etching barrier layer 110 may be made of a dielectric material different than polysilicon. For example, the etching barrier layer 110 may be made of silicon carbonitride (SiCN), a carbon-containing material carbon-containing silicon oxide or silicon nitride (e.g., SiOC, SiOCN), the like, or combinations thereof. In some embodiments, the etching barrier layer 110 may be made of a metal-containing material, such as tungsten, titanium, titanium nitride, the like, or combinations thereof. In some embodiments, the etching barrier layer 110 may be made of metal oxide. In some embodiments, the etching barrier layer 110 may be made of a material having a dielectric constant greater than about 7.9 (e.g., high dielectric constant (high-k) material). For example, the etching barrier layer 110 may be made of hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), the like, or combinations thereof. In some embodiments, the etching barrier layer 110 may have a thinner thickness than the overlying conductive layer 112a.

In some embodiments, the etching barrier layer 110 may be made of a different material than the underlying dielectric layer 108 and have a high etching selectivity relative to the underlying dielectric layer 108. For example, the etching selectivity, which is the ratio of the etching rate of the etching barrier layer 110 to the dielectric layer 108, is greater than about 5 when the etching barrier layer 110 is etched. In some embodiments, a ratio of the etching rate of the etching barrier layer 110 to the etching rate of the dielectric layer 108 may be greater than about 10. If the ratio of the etching rate of the etching barrier layer 110 to the etching rate of the dielectric layer 108 is less than about 5, the hole etch process (see FIG. 4) would significantly consume the dielectric layer 108 and further consume the underlying interconnect 106, which in turn adversely affects the performance of the semiconductor device.

By way of example and not limitation, the dielectric layer 108 may be made of an oxide-containing material (e.g., SiO₂), a nitrogen-containing material (e.g., SiON, SiN, Si₃N₄), a carbon-containing material (e.g., SiOC, SiOCN), the like, or combinations thereof. In some embodiments, the dielectric layer 108 may be formed of an oxide such as Phospho-Silicate Glass (PSG), Boron-Silicate Glass (BSG), Boron-Doped Phospho-Silicate Glass (BPSG), Tetra Ethyl Ortho Silicate (TEOS) oxide, the like, or combinations thereof. In some embodiments, the etching barrier layer 110 may have a thickness thinner than or equal to the underlying dielectric layer 108.

In some embodiments, the etching barrier layer 110 can be implanted with a dopant to improve the etching selectivity relative to the overlying conductive layer 112a and/or the underlying dielectric layer 108. By way of example and not limitation, the dopant may be selected form a group including silicon (Si), germanium (Ge), carbon (C), aluminum (Al), or combinations thereof. In some embodiments, the dopant can be distributed in the etching barrier layer 110 in a gauss manner. In some embodiments, the dopant atomic concentration in the etching barrier layer 110 may be in a range from about 1% to about 90%, such as 1, 5, 10, 15, 20, 25, 30, 35, 40, 45, 50, 55, 60, 65, 70, 75, 80, 85, or 90 atomic %. The atomic concentration which elements implanted in the etching barrier layer 110 described above is given for illustrative purposes. Various atomic concentrations which elements implanted in the layers are within the contemplated scope of the present disclosure. In some embodiments, the etching barrier layer 110 has a higher dopant atomic concentration than the underlying dielectric layer 108. In some embodiments, the dielectric layer 108 is dopant-free.

As shown in FIGS. 1A and 1B, the conductive layer 112a, the middle sacrificial layer 112b, and the conductive layer 112c are formed to stack on the etching barrier layer 110, and other embodiments may contain more or fewer conductive layers/sacrificial layers. The middle sacrificial layer 112b (e.g., polysilicon, silicon nitride, etc.) is a sacrificial layer that can be replaced and then replaced with highly doped polysilicon to serve as a common source line of the memory devices. In addition, a dielectric layer 114a is formed to sandwich between the conductive layer 112a and the middle sacrificial layer 112b, and a dielectric layer 114b is formed to sandwich between the middle sacrificial layer 112b and the conductive layer 112c.

As shown in FIGS. 1A and 1B, a plurality of gate layers 120 and a plurality of insulating layers 116a and 136a laterally extend above the conductive layer 112a, the middle sacrificial layer 112b, and the conductive layer 112c and are alternatively stacked on the semiconductor substrate 101 along Z-direction. A memory layer 150 and a channel layer 152 are formed to extend upwardly above the substrate 101 and through the conductive layer 112a, the middle sacrificial layer 112b, and the conductive layer 112c and the gate layers 120, and the memory layer 150 is laterally between the channel layer 152 and the gate layers 120. In some embodiments, the channel layer 152 can have a U-shaped cross-sectional profile. A plurality of memory cells 162 can be defined at the points of intersection between the gate layers 160, the memory layer 150, and the channel layer 152. In addition, a dielectric material 154 is deposited over the channel layer 152, such that the channel layer 152 cups an underside of the dielectric material 154. A bonding pad 156 is formed over the dielectric material 154 to form an electrical contact with the channel layer 108.

As shown in FIGS. 1A and 1B, a capping layer 158 is formed over the bond pads 156, the gate layers 160, and the insulating layers 116a and 136a. The capping layer 158 may be made of dielectric material, such as silicon oxide, silicon nitride (SiN), silicon oxynitride (SiON), silicate, the like, or combinations thereof. A metal plug 166 is formed to extend through the capping layer 158, the gate layers 120, and the insulating layers 116a and 136a. A dielectric spacer 164 laterally surrounds the metal plug 166, such that the metal plug 166 can be electrically insulated from the gate layers 120 by the dielectric spacer 164. An ILD layer 170 is formed over the capping layer 158. A plurality of bit lines 172 is in the ILD layer 170 and electrically connected to the bonding pads 156 with an interconnection via 174 formed in the ILD layer 170.

Reference is made to FIG. 1C. FIG. 1C illustrates a local enlarged view of an IC structure corresponding to FIG. 1B according to some embodiments of the present disclosure. While FIG. 1C shows a different embodiment of the IC structure than the semiconductor structure in FIGS. 1A and 1B. In addition, the present disclosure may repeat reference numerals and/or letters in the various examples. This repetition is for the purpose of simplicity and clarity and does not in itself dictate a relationship between the various embodiments and/or configurations discussed. It is noted that, the difference between the present embodiment and the embodiment in FIGS. 1A and 1B is in that a dielectric layer 408 is formed to sandwich between the etching barrier layer 110 and the conductive layer 112a and made of a different material than the etching barrier layer 110 and/or the conductive layer 112a and acts as an etch buffer layer. In some embodiments, the dielectric layer 408 can be made of a same material as the underlying dielectric layer 108. By way of example and not limitation, both of the dielectric layers 108 and 408 can be made of silicon oxide. In some embodiments, the dielectric layer 408 can be made of a different material than the underlying dielectric layer 108. By way of example and not limitation, one of the dielectric layers 108 and 408 can be made of silicon oxide, and another one of the dielectric layers 108 and 408 can be made of silicon nitride.

In some embodiments, the dielectric layer 408 may be made of an oxide-containing material (e.g., SiO₂), a nitrogen-containing material (e.g., SiON, SiN, Si₃N₄), a carbon-containing material (e.g., SiOC, SiOCN, or SiC), the like, or combinations thereof. In some embodiments, the dielectric layer 408 may be made of a material having a dielectric constant greater than about 7.9 (e.g., high dielectric constant (high-k) material). For example, the dielectric layer 408 may be made of hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), the like, or combinations thereof. In some embodiments, the dielectric layer 408 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, the like, or combinations thereof. In some embodiments, the dielectric layer 408 may have a thickness thinner than, thicker than, or equal to the underlying etching barrier layer 110.

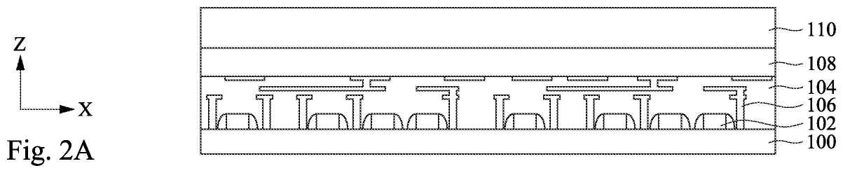

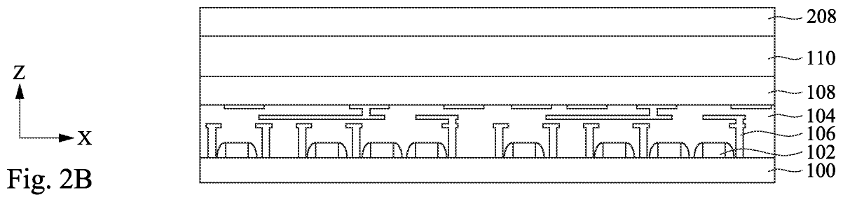

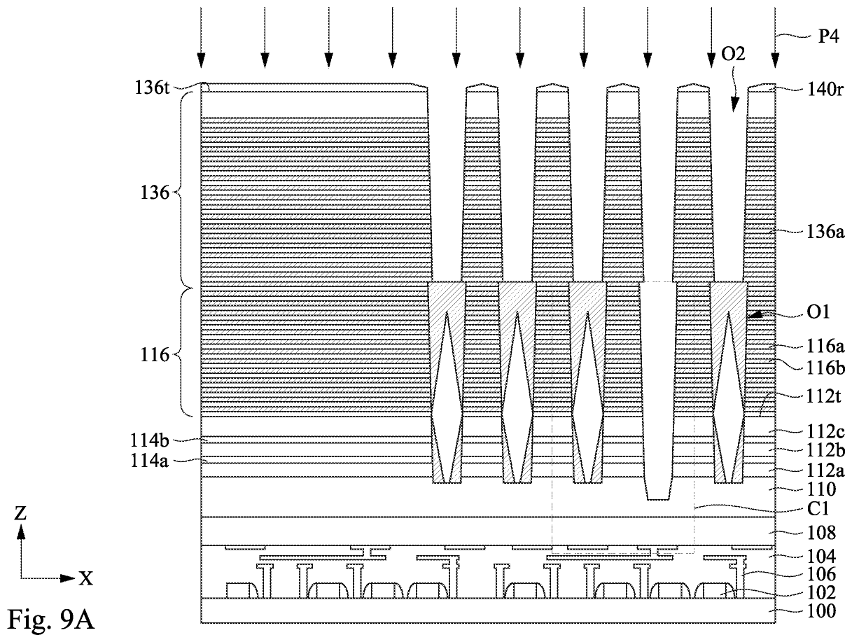

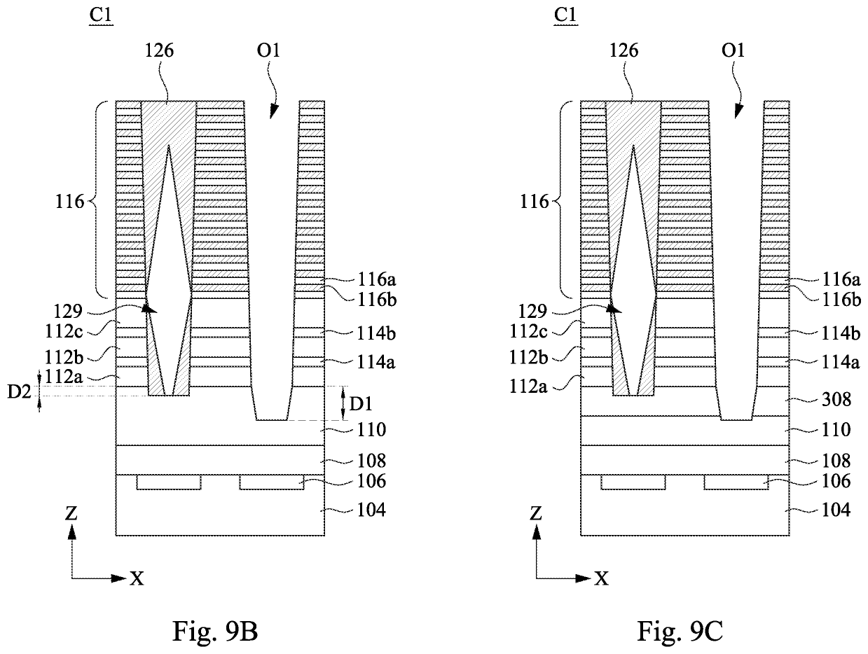

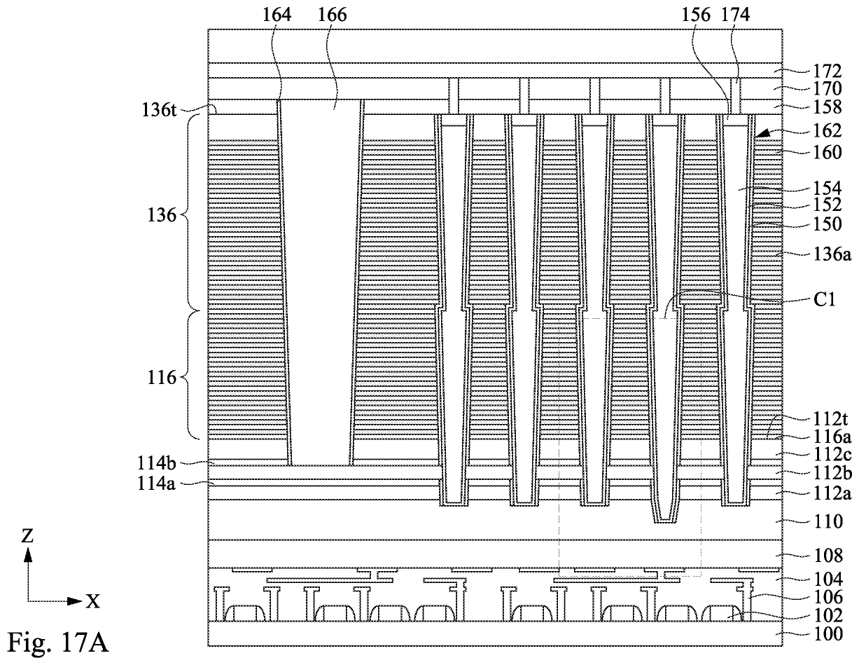

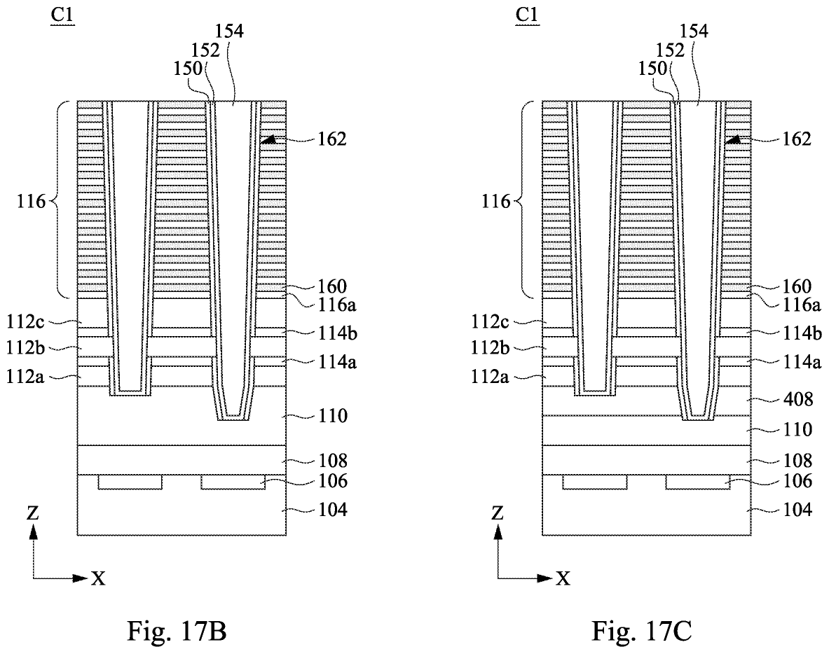

Reference is made to FIGS. 2A, 3-9B, and 10-17B. FIGS. 2A, 3-9A, and 10-17A are cross-sectional views illustrating a method in various stages of forming an IC structure in accordance with some embodiments of the present disclosure. FIGS. 9B and 17B illustrate local enlarged views of the IC structure according to the region Cl in FIGS. 9A, and 17A, respectively.

Reference is made to FIG. 2A. A plurality of complementary metal oxide semiconductors (CMOS) 102 are formed on the substrate 100. The substrate 100 can be a semiconductor substrate, such as a monocrystalline silicon bulk semiconductor, a semiconductor-on-insulator (SOI) substrate, or the like, which may be doped (e.g., with a p-type or an n-type impurity) or undoped. The substrate 100 may be a wafer, such as a silicon wafer. Generally, a SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used.

In some embodiments, the semiconductor material of the substrate 100 may include silicon; germanium; a compound semiconductor including silicon carbide, gallium arsenide, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; the like; or combinations thereof. The CMOS 102 may include PMOS and/or NMOS.

Subsequently, an inter-layer dielectric (ILD) layer 104 is formed on the CMOS 102. An interconnect 106 is formed in the ILD layer 104 and is electrically connected to subsequent source lines (SL). Subsequently, a dielectric layer 108 is deposited on the ILD layer 104 and the interconnect 106. Subsequently, an etching barrier layer 110 is deposited on the dielectric layer 108 and made of a different material than the underlying dielectric layer 108, such that the etching barrier layer 110 can act as an etch stop layer or an etch buffer layer during a hole etch process (see FIG. 4), and thus a consumption in underlying interconnect 106 can be avoided, in which the hole etch process is performed to form a vertical channel hole where a vertical channel formation (see FIG. 8) will be formed therein. If the etching barrier layer 110 is not formed between the dielectric layer 108 and the conductive layer 112a (see FIG. 3), the hole etch process (see FIG. 4) would significantly consume the dielectric layer 108 and further consume the underlying interconnect 106, which in turn adversely affects the performance of the IC structure.

The same or similar configurations and/or materials of the etching barrier layer 110 as described with FIGS. 1A and 1B may be employed in FIG. 2A, and thus are not repeated herein for the sake of clarity. Therefore, reference may be made to the foregoing paragraphs for the related detailed descriptions, and are not described again herein. In some embodiments, the dielectric layer 108 can be interchangeably referred to an interface film. In some embodiments, the dielectric layer 108 may be made of a different material than the ILD layer 104.

Reference is made to FIG. 2B. FIG. 2B illustrates a cross-sectional view of an IC structure corresponding to FIG. 2A according to some embodiments of the present disclosure. While FIG. 2B shows a different embodiment of the IC structure than the semiconductor structure in FIG. 2A. In addition, the present disclosure may repeat reference numerals and/or letters in the various examples. This repetition is for the purpose of simplicity and clarity and does not in itself dictate a relationship between the various embodiments and/or configurations discussed. It is noted that, the difference between the present embodiment and the embodiment in FIG. 2A is in that a dielectric layer 208 is formed to sandwich between the etching barrier layer 110 and the conductive layer 112a and made of a different material than the etching barrier layer 110 and/or the conductive layer 112a and acts as an etch buffer layer. In some embodiments, the dielectric layer 208 can be made of a same material as the underlying dielectric layer 108. By way of example and not limitation, both of the dielectric layers 108 and 208 can be made of silicon oxide. In some embodiments, the dielectric layer 208 can be made of a different material than the underlying dielectric layer 108. By way of example and not limitation, one of the dielectric layers 108 and 208 can be made of silicon oxide, and another one of the dielectric layers 108 and 208 can be made of silicon nitride.

In some embodiments, the dielectric layer 208 may be made of an oxide-containing material (e.g., SiO₂), a nitrogen-containing material (e.g., SiON, SiN, Si₃N₄), a carbon-containing material (e.g., SiOC, SiOCN, or SiC), the like, or combinations thereof. In some embodiments, the dielectric layer 208 may be made of a material having a dielectric constant greater than about 7.9 (e.g., high dielectric constant (high-k) material). For example, the dielectric layer 208 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), the like, or combinations thereof. In some embodiments, the dielectric layer 208 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, the like, or combinations thereof. In some embodiments, the dielectric layer 208 may have a thickness thinner than, thicker than, or equal to the underlying etching barrier layer 110.

Reference is made to FIG. 3. At least one conductive layer is formed over the etching barrier layer 110 and located under a plurality of memory cells and connected to the plurality of memory cells (see FIG. 1A). As shown in FIG. 3, the conductive layer 112a, the middle sacrificial layer 112b, and the conductive layer 112c are formed to stack on the etching barrier layer 110, and other embodiments may contain more or fewer conductive layers. In some embodiments, the conductive layer 112a, the middle sacrificial layer 112b, and the conductive layer 112c can be made of polysilicon and can be interchangeably referred to polysilicon layers. In some embodiments, the middle sacrificial layer 112b (e.g., polysilicon, silicon nitride, etc.) is a sacrificial layer that can be replaced and then replaced with highly doped polysilicon and can be interchangeably referred to a common conductive layer or a common source line. In addition, a dielectric layer 114a is formed to sandwich between the conductive layer 112a and the middle sacrificial layer 112b, and a dielectric layer 114b is formed to sandwich between the middle sacrificial layer 112b and the conductive layer 112c. In some embodiments, the conductive layer 112a, the middle sacrificial layer 112b, and the conductive layer 112c can be made of a conductive material, such as polysilicon, tungsten, aluminum, copper, the like, other suitable conductive materials, or combinations thereof. In some embodiments, the dielectric layers 114a and 114b may be made of an oxide-containing material (e.g., SiO₂), a nitrogen-containing material (e.g., SiON, SiN, Si₃N₄), a carbon-containing material (e.g., SiOC, SiOCN), the like, or combinations thereof.

Subsequently, a first multi-layered stack 116 including alternating insulating layers 116a and sacrificial layers 116b is formed on the conductive layer 112a, the middle sacrificial layer 112b, and the conductive layer 112c. The insulating layers 116a and the sacrificial layers 116b are parallel to each other and alternatively stacked on the semiconductor substrate 100 along Z-direction. In some embodiments, the first multi-layered stack 116 can be interchangeably referred to a film stack or a deck of ON pairs. However, it should be appreciated that, in the embodiments of the present disclosure, the sacrificing layers 116b and the insulating layers 116a are made of different material. For example, the sacrificial layers 116b may be made of silicon nitride, and the insulating layers 116a may be made of silicon oxide. In some embodiments, the sacrificial layers 116b and the insulating layers 116a can be formed by low pressure chemical vapor deposition (LPCVD) process.

Subsequently, a hard mask layer 120, a transfer layer 122, and a photo resist layer 124 are formed on the first multi-layered stack 116 in sequence. In some embodiments, the hard mask layer 120 can also act as a transfer layer and made of a material, such as amorphous carbon, and forms a carbon-ON interface with the first multi-layered stack 116. The transfer layer 122 can be a single layer or multi-layer structure. As shown in FIG. 3, the transfer layer 122 can be a tri-layer structure including a bottom layer 122a, a middle layer 122b over the bottom layer 122a, and a top layer 122c over the middle layer 122b. In some embodiments, the bottom layer 122a may be a dielectric anti-reflection coating (DARC) layer. The middle layer 122b can be a photoresist material used in a photolithography process or a carbon doped organic material (carbon doped organic material), and its main function is to use it when the thickness of the photoresist layer 124 is too thin to resist the etching transfer pattern to the bottom layer 122a. The top layer 122c is a bottom anti-reflective coating (BARC) for reducing reflection during the photolithography process. In some embodiments, the top layer 122c is made of a silicon-containing BARC material, such as silicon-enriched BARC.

The photo resist layer 124 may be a positive photoresist layer or a negative photoresist layer. In some embodiments, the photo resist layer 124 may be made of poly methyl methacrylate (PMMA), poly methyl glutarimide (PMGI), phenol formaldehyde resin (DNQ/Novolac). In some embodiments, the photo resist layer 124 may further include a photo-sensitive element, such as a photo-acid generator (PAG). This allows a photolithography process to be performed to pattern the photo resist layer 124. In some embodiments, the photo resist layer 124 may be made of a CxHyOz material. The photo resist layer 124 can be patterned by a photolithography process, which may include one or more exposure, developing, rinsing, and baking processes. The photolithography process patterns the photo resist layer 124 into a photoresist mask, which may have one or more via holes, trenches, and/or openings that expose the transfer layer 122 therebelow. The transfer layer 122 is then etched using the photoresist mask to form a patterned transfer layer 122 (see FIG. 4), and the hard mask layer 120 is then etched using the patterned transfer layer 122 to form a patterned hard mask layer 120 (see FIG. 4). The patterned hard mask layer 120 is then used to pattern the various layers below, such as first multi-layered stack 116.

Reference is made to FIG. 4. An etching process P1, such as a hole etch process, is performed to form a plurality of through openings O1 passing through the first multi-layered stack 116 and stop at the etching barrier layer 110. In some embodiments, the etching process P1 can be an anisotropic etching process, such as a reactive ion etching (RIE) process, performed on the first multi-layered stack 116 using hard mask layer 120, a transfer layer 122, and a photo resist layer 124 as etching masks. In some embodiments, the etching process P1 may lead to a loss (i.e., the loss of the hard mask layer 120, the transfer layer 122, and the photo resist layer 124). Therefore, after the etching process P1 is complete, remainders 120r of the hard mask layer 120 may remain and form on the first multi-layered stack 116. In some embodiments, the etching process P1 would consume the etching barrier layer 110 exposed from the through openings O1, and thus the etching barrier layer 110 may be damaged as shown in FIG. 4. The through openings O1 may be a plurality of circular through holes passing through the first multi-layered stack 116 along Z-direction and terminate at the surface 110t of the etching barrier layer 110. The through openings O1 can be used to expose portions of the sacrificial layers 116b and the insulating layers 116a serving as sidewalls of the through openings O1. In some embodiments, the through openings O1 can be interchangeably referred to as vertical channel openings.

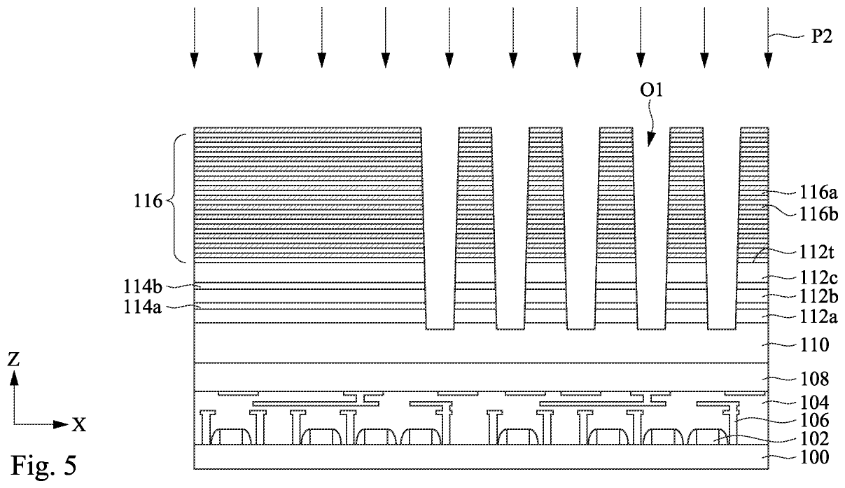

Reference is made to FIG. 5. After the etching process P1 shown in FIG. 4 is complete, the remainders 120r of the hard mask layer 120 can be removed with a removing process P2, such as an ashing process, a wet clean process, an oxygen plasma dry etching process, or the like.

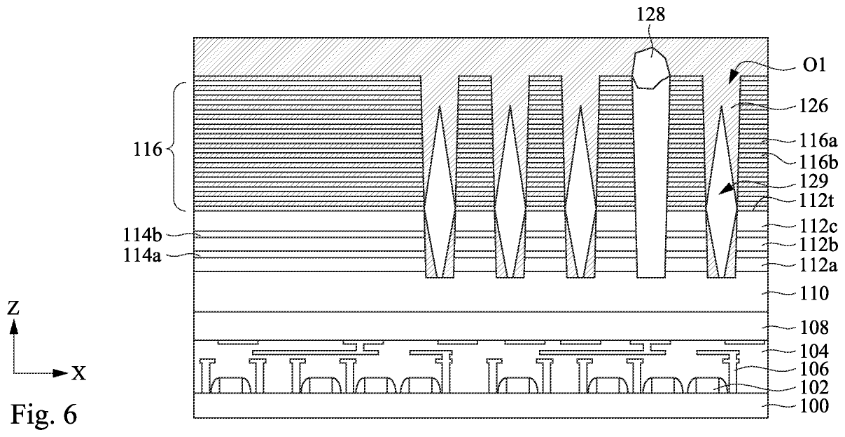

Reference is made to FIG. 6. A filling material 126 is deposited over the first multi-layered stack 116 and filled into the through openings O1 to provide structural support for the various features therearound. However, a defect 128, (e.g., particle or residue) may fall onto the through opening O1 and block the topography of the through opening O1 during the deposition of the filling material 126, which in turn prevents the filling material 126 from filling the through opening O1. Therefore, the through opening O1 directly underlying the defect 128 is free of filling material 126 therein, and thus the etching barrier layer 110 is exposed from the through opening O1. In some embodiments, the defect 128 may have a different material than the filling material 126, such as polymer.

In some embodiments, after the deposition of the filling material 126 is complete, due to the high aspect ratio of the through openings O1, a seam 129 may be formed in the through opening O1 surrounded by the filling material 126, result in a gap-filled with seam. In some embodiments, the seam 129 can be interchangeably referred to an air gap. In some embodiments, the filling material 126 can be made of a carbon-containing material, such as amorphous carbon, and the deposition of the filling material 126 can serve as a carbon filler gap-filling process.

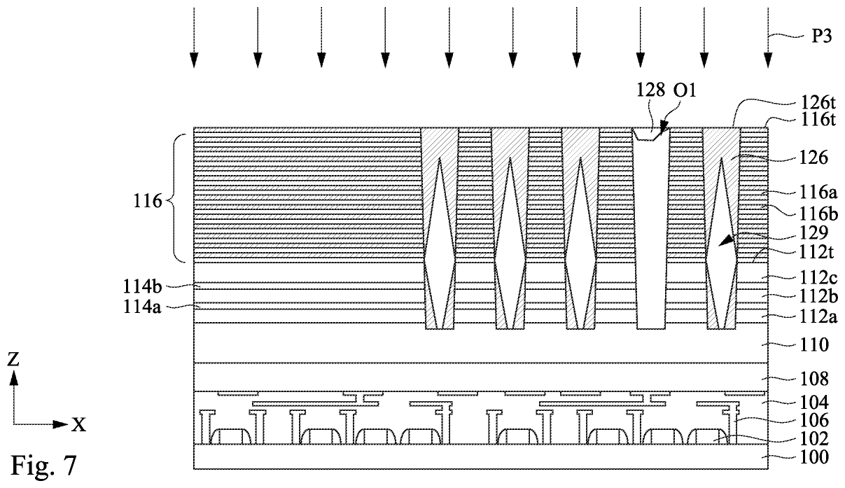

Reference is made to FIG. 7. A planarization process P3, such as a chemical mechanical polish (CMP) process, using the first multi-layered stack 116 as a stop layer is performed to remove portions of the filling material 126 above the first multi-layered stack 116. Therefore, the filling material 126 has a top surface 126t substantially level with a top surface 116t of the first multi-layered stack 116. As shown in FIG. 7, the defect 128 may still remain on the through opening O1 to block the through opening O1.

Reference is made to FIG. 8. A second multi-layered stack 136 including alternating insulating layers 136a and sacrificial layers 136b is formed on the first multi-layered stack 116. The insulating layers 136a and the sacrificial layers 136b are parallel to each other and alternatively stacked on the first multi-layered stack 116 100 along Z-direction. In some embodiments, the multi-layered stack 136 can be interchangeably referred to a film stack or a deck of ON pairs. However, it should be appreciated that, in the embodiments of the present disclosure, the sacrificing layers 136b and the insulating layers 136a are made of different material. For example, the sacrificial layers 136b may be made of silicon nitride, and the insulating layers 136a may be made of silicon oxide. In some embodiments, the sacrificial layers 136b and the insulating layers 136a can be formed by low pressure chemical vapor deposition (LPCVD) process.

Subsequently, a hard mask layer 140, a transfer layer 142, and a photo resist layer 144 are formed on the second multi-layered stack 136 in sequence. In some embodiments, the hard mask layer 140 can act as a transfer layer and made of a material, such as amorphous carbon, and forms a carbon-ON interface with the second multi-layered stack 136. The transfer layer 142 can be a single layer or multi-layer structure. As shown in FIG. 8, the transfer layer 142 can be a tri-layer structure including a bottom layer 142a, a middle layer 142b over the bottom layer 142a, and a top layer 142c over the middle layer 142b. In some embodiments, the bottom layer 142a may be a dielectric anti-reflection coating (DARC) layer 142a. The middle layer 142b can be a photoresist material used in a photolithography process or a carbon doped organic material (carbon doped organic material), and its main function is to use it when the thickness of the photoresist layer 144 is too thin to resist the etching transfer pattern to the bottom layer 142a. The top layer 142c is a bottom anti-reflective coating (BARC) for reducing reflection during the photolithography process. In some embodiments, the top layer 142c is made of a silicon-containing BARC material, such as silicon-enriched BARC.

The photo resist layer 144 may be a positive photoresist layer or a negative photoresist layer. In some embodiments, the photo resist layer 144 may be made of Poly (methyl methacrylate) (PMMA), Poly (methyl glutarimide) (PMGI), Phenol formaldehyde resin (DNQ/Novolac). In some embodiments, the photo resist layer 144 may further include a photo-sensitive element, such as a photo-acid generator (PAG). This allows a photolithography process to be performed to pattern the photo resist layer 144. In some embodiments, the photo resist layer 144 may be made of a CxHyOz material. The photo resist layer 144 can be patterned by a photolithography process, which may include one or more exposure, developing, rinsing, and baking processes. The photolithography process patterns the photo resist layer 144 into a photoresist mask, which may have one or more via holes, trenches, and/or openings that expose the transfer layer 142 therebelow. The transfer layer 142 is then etched using the photoresist mask to form a patterned transfer layer 142 (see FIG. 9A), and the hard mask layer 140 is then etched using the patterned transfer layer 142 to form a patterned hard mask layer 140 (see FIG. 9A). The patterned hard mask layer 140 is then used to pattern the various layers below, such as second multi-layered stack 136.

Reference is made to FIGS. 9A and 9B. An etching process P4, such as a hole etch process, is performed to form a plurality of through openings O2 passing through the multi-layered stack 136. In some cases where the defect 128 (see FIG. 8) not falls onto the through opening O1, the etching process P4 can be performed until the filling material 126 is exposed. In some cases where the defect 128 (see FIG. 8) falls onto the topography of the through opening O1, the etching process P4 can be performed to remove the defect 128 and stop at the etching barrier layer 110, such that the underlying interconnect 106 and dielectric layer 108 can remain covered by the etching barrier layer 110, which in turn allows for preventing the underlying interconnect 106 from damaging by the etching process P4. In some embodiments, the etching process P4 would consume the etching barrier layer 110 exposed from the through openings O1 and O2, and thus the etching barrier layer 110 may be damaged as shown in FIGS. 9A and 9B. As shown in FIG. 9B, after the etching process P4 is complete, a depth D1 of the through opening O1 in the etching barrier layer 110 that was originally covered with the defect 128 (see FIG. 8) can be greater than a depth D2 of the through opening O1 in the etching barrier layer 110 that was not originally covered with the defect 128.

In some embodiments, the etching process P4 can be an anisotropic etching process, such as a reactive ion etching (RIE) process, performed on the multi-layered stack 136 using hard mask layer 140, a transfer layer 142, and a photo resist layer 144 as etching masks. In some embodiments, the etching process P4 may lead to a loss (i.e., the loss of the hard mask layer 140, the transfer layer 142, and the photo resist layer 144). Therefore, after the etching process P4 is complete, remainders 140r of the hard mask layer 140 may remain and form on the first multi-layered stack 136. The through openings O2 may be a plurality of circular through holes passing through the multi-layered stack 136 along Z-direction and overlapping with the through openings O1. The through openings O2 can be used to expose portions of the sacrificial layers 136b and the insulating layers 136a serving as sidewalls of the through openings O2. In some embodiments, the through openings O2 can be interchangeably referred to as vertical channel openings. After the etching process P4 is complete, the remainders 140r of the hard mask layer 140 can be removed with a removing process, such as an ashing process, a wet clean process, an oxygen plasma dry etching process, or the like.

Reference is made to FIG. 9C. FIG. 9C illustrates a local enlarged view of IC structure corresponding to FIG. 9B according to some embodiments of the present disclosure. While FIG. 9C shows an embodiment of the IC structure further including a dielectric layer 308 than the semiconductor structure in FIGS. 9A and 9B. In addition, the present disclosure may repeat reference numerals and/or letters in the various examples. This repetition is for the purpose of simplicity and clarity and does not in itself dictate a relationship between the various embodiments and/or configurations discussed. The dielectric layer 308 is similar to the dielectric layer 208 as shown in FIG. 2B, and thus relevant details will not be repeated for brevity. It is noted that, in some cases where the defect 128 falls onto the through opening O1, the etching process P4 can be performed to remove the defect 128 and further etch the dielectric layer 208. Subsequently, the etching process P4 can stop at the etching barrier layer 110, such that the underlying interconnect 106 and dielectric layer 108 can remain covered by the etching barrier layer 110, which in turn allows for preventing the underlying interconnect 106 from damaging by the etching process P4. In some embodiments, the etching process P4 would consume the etching barrier layer 110 exposed from the through opening O1, and thus the etching barrier layer 110 may be damaged as shown in FIG. 9C.

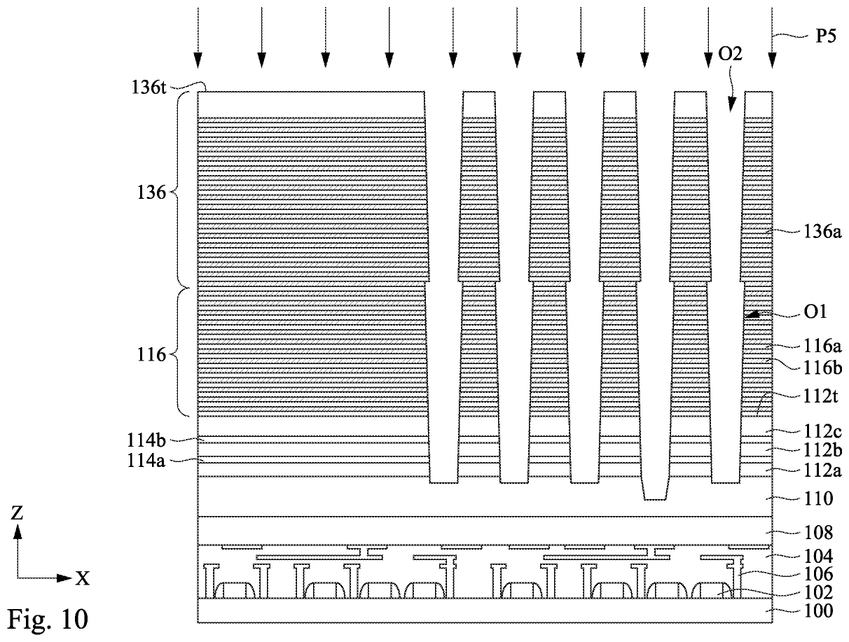

Reference is made to FIG. 10. After the etching process P4 shown in FIGS. 9A and 9B is complete, the filling material 126 can be removed with a removing process P5, such as an ashing process, a wet clean process, an oxygen plasma dry etching process, or the like.

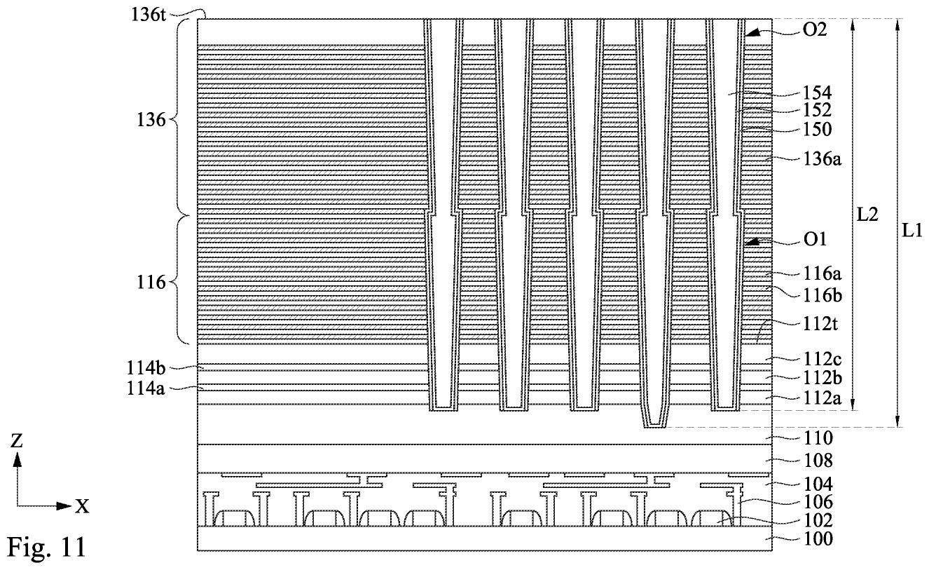

Reference is made to FIG. 11. A memory layer 150 and a channel layer 152 are formed in sequence on sidewalls of the through openings O1 and O2. Therefore, the memory layer 150 is disposed between the channel layer 152 and the sacrificial layers 116b and 136b. In some embodiments, the memory layer 150 may include a composite layer having (but not limited to) oxide-nitride-oxide (ONO), oxide-nitride-oxide-nitride-oxide (ONONO) or oxide-nitride-oxide-nitride-oxide-nitride-oxide (ONONONO) structure formed to conformally blanket over the first and second multi-layered stacks 116 and 136 and the sidewalls and bottoms of the through openings O1 and O2. Subsequently, an etching process is performed to remove portions of the composite layer disposed on a top surface 136t of the second multi-layered stack 136 and on the bottoms of the through openings O1.

Thereafter, the channel layer 152 is conformally deposited over the memory layer 150, and thus the IC structure may include a vertical channel flash memory device. The channel layer 152 is in contact with the conductive layer 112a, the middle sacrificial layer 112b, and the conductive layer 112c. In addition, as shown in FIG. 11, a vertical dimension L1 (e.g. length) of the channel 152 extending in the through opening O1 that was originally covered with the defect 128 (see FIG. 8) can be greater than a vertical dimension L2 (e.g. length) of the channel 152 extending in the through opening O1 that was not originally covered with the defect 128. In some embodiments, the memory layer 150 may be made of semiconductor material, such as such as poly-silicon (Si), Ge or other doped/undoped semiconductor material. For example, the channel layer 152 may be made of doped poly-silicon.

Subsequently, a dielectric material 154 is deposited over the channel layer 152 and fills in the through openings O1 and O2. In some embodiments, the dielectric material 154 may be made of, such as silicon dioxide (SiO₂). In some embodiments, the dielectric material 154 may be made of a same material as the insulating layers 116a and the insulating layers 136a. In some embodiments, the dielectric material 154 may be made of a different material than the insulating layers 116a and the insulating layers 136a. Subsequently, a planarization process is performed to remove the excessive dielectric material 154 and channel layer 152 above the top surface 136t of the second multi-layered stack 136. As a result of this method, the channel layer 152 wraps around the dielectric material 154 in the through openings O1 and O2. The memory layer 150 wraps around the channel layer 152 in the through openings O1 and O2.

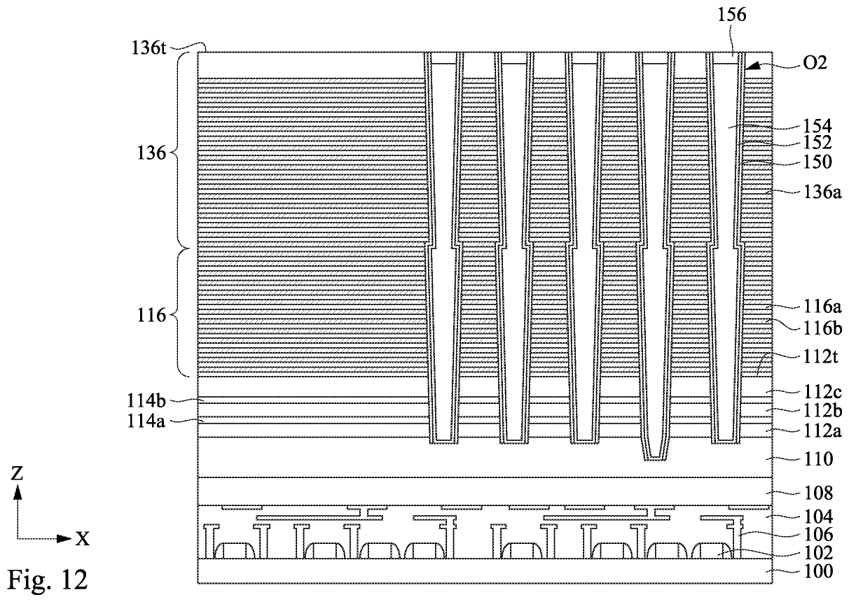

Reference is made to FIG. 12. An etching back process is performed on the dielectric material 154 to reappear upper portions of the through openings O2. In some embodiments, the etching back process performing along a surface of the channel layer 152 may be a dry etching process. For example, the dry etching process may be performed using HF/NH₃ or NF₃/NH₃ as the etching gas. Subsequently, bonding pads 156 are formed in the upper portions of the through openings O2 and on the dielectric material 154 to form an electrical contact with the channel layer 152. In some embodiments, the bonding pads 156 are formed by depositing a poly-silicon (Si), Ge, normally, n-type dopants (N⁺), such as phosphorus or arsenic over the second multi-layered stack 136. Subsequently, a planarization process is performed to remove the excessive semiconductor material above the top surface 136t of the second multi-layered stack 136. As a result of this method, the bonding pads 156 can be formed as shown in FIG. 12. In some embodiments, the bonding pad 156 can be a P⁺ poly-silicon pad.

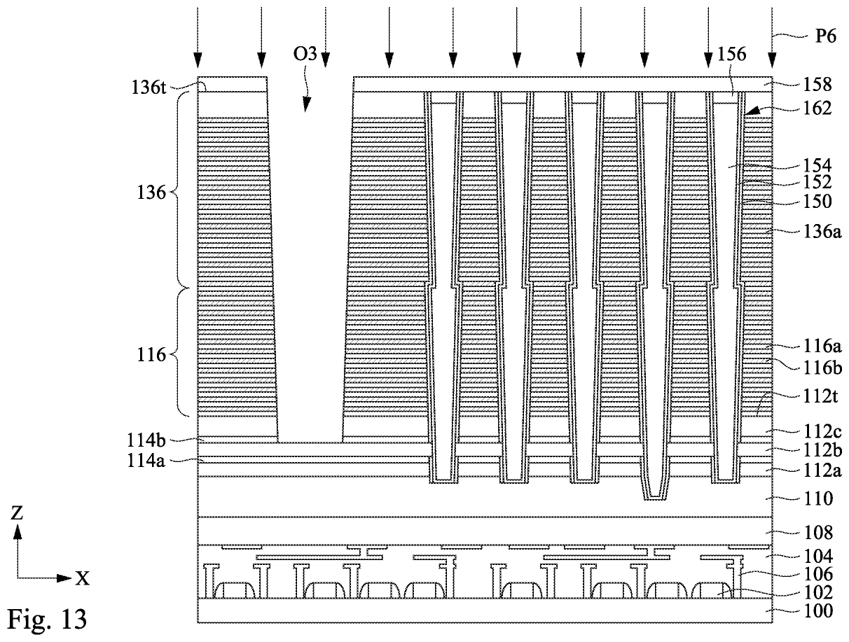

Reference is made to FIG. 13. After performing the etching back process on the bonding pads 156, a capping layer 158 is deposited over the bond pads 156 and the second multi-layered stack 136. The capping layer 158 may be made of dielectric material, such as silicon oxide, silicon nitride (SiN), silicon oxynitride (SiON), silicate or the arbitrary combinations thereof. Subsequently, an etching process P6 is performed to form a through opening O3 passing through the first and second multi-layered stacks 116 and 136 along the Z-direction and terminating at the top surface 112t of conductive layer 112c, so as to partially expose the sacrificing layers 116b and 136b and the insulating layers 116a and 136a. In some embodiments, the etching process P6 can be an anisotropic etching process, such as a reactive ion etching (RIE) process, performed on the first and second multi-layered stack 116 and 136 using a patterned hard mask layer (not shown) as an etching mask. In some embodiments, the through opening O3 can be interchangeably referred to a slit trench, a conductive layer trench, or a source line trench.

After forming the through opening O3 (i.e., slit trench or source line trench), a composite protective layer (e.g., silicon nitride-silicon oxide-silicon nitride) can be deposited on the sidewall of the through opening O3. Subsequently, the bottom of the through opening O3 can be opened by an anisotropic etching that can stop at the middle sacrificial layer 112b. Subsequently, the middle sacrificial layer 112b can be dissolved by the solution to form an underground hollow channel, and then a highly reactive gas/solution (e.g., hydrofluoric acid/ammonia (HF/NH₃) or nitrogen trifluoride/ammonia (NF₃/NH₃)) can be used as an etching gas/solution to remove the ONO memory layer 150 through the underground hollow channel to expose the polysilicon channel layer 152. Subsequently, a high-concentration doped polysilicon can be filled in the underground hollow channel to complete the connection of the common conductive layer or the common source line (not shown). Subsequently, the composite protective layer (not shown) formed on the sidewall of the through opening O3 which is formed only by silicon nitride can be removed by the solution.

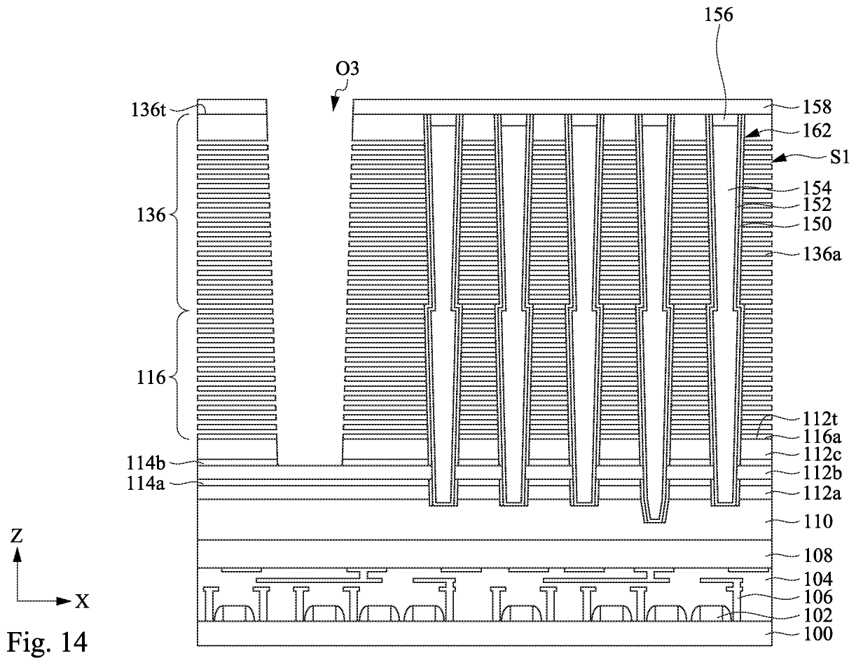

Reference is made to FIG. 14. The sacrificial layers 116b and 136b are removed by a solution, such as using phosphoric acid (H₃PO₄) solution, through the through opening O3 to expose portions of the memory layer 150. Therefore, spaces 51 are formed to inherit the shapes of the sacrificial layers 116b and 136b.

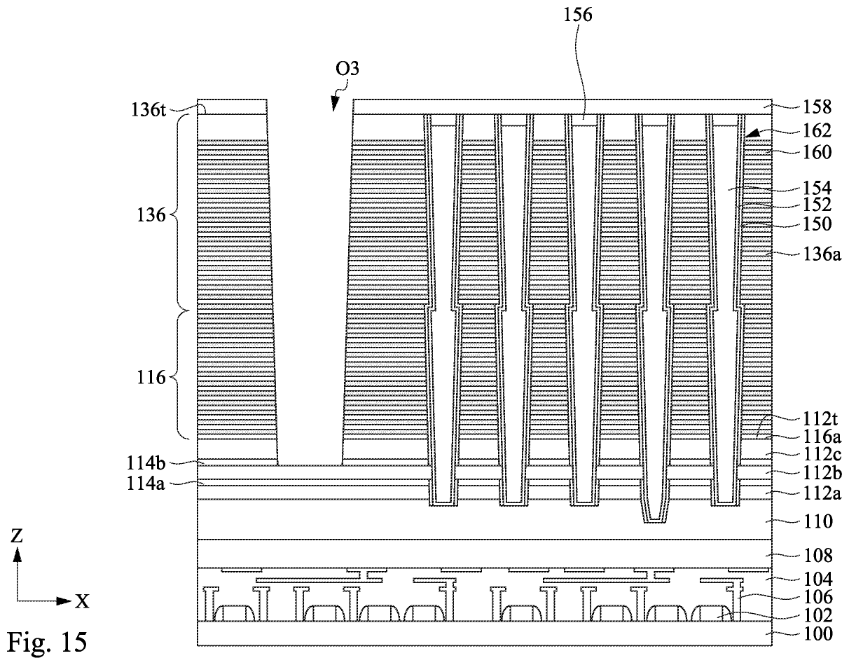

Reference is made to FIG. 15. A plurality of gate layers 160 are formed in the spaces 51 through the through opening O3. As a result, a plurality of memory cells 162 can be defined at the points of intersection between the gate layers 160, the memory layer 150, and the channel layer 152, so as to form a memory cell array in the first and second multi-layered stacks 116 and 136, such that a 2-deck 3D NAND CuA architecture can be formed. In some embodiments, the memory cells 162 can be interchangeably referred to memory devices. In some embodiments, the gate layers 160 may include poly-silicon, metal or other suitable conductive material. In some embodiments, the gate layers 160 may include metal layers, such as TiN/W, TaN/W, TaN/Mo, or the like. In some embodiments, the gate layers 160 may include dielectric layer, such as AlOₓ. For example, each of the gate layers 160 can be a multi-layered structure including a high-K material layer (e.g., HfOₓ layer or AlOₓ layer), a TiN layer, and a tungsten layer.

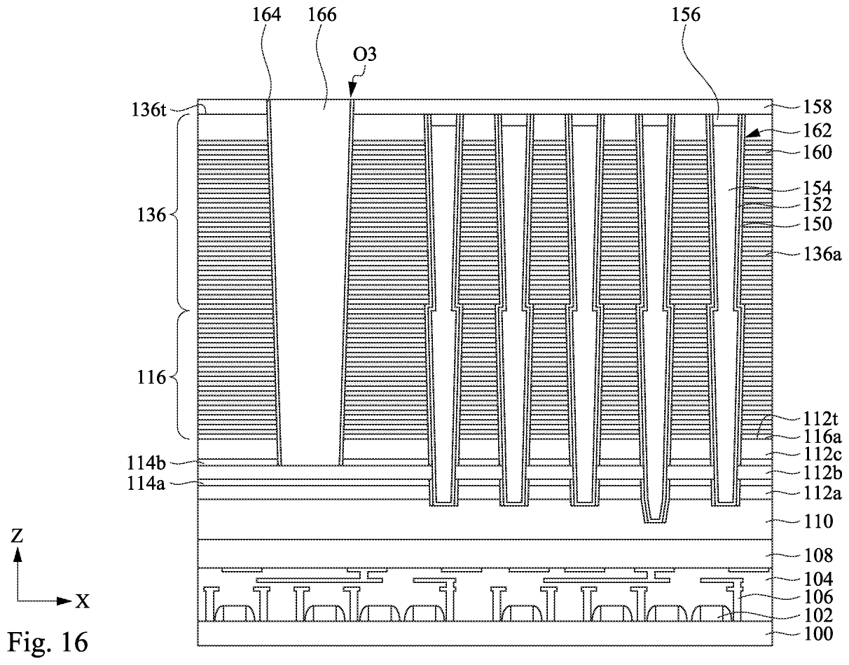

Reference is made to FIG. 16. A dielectric spacer 164 may be formed on the sidewalls of the through opening O3. Subsequently, a metal plug 166 may be formed in the dielectric spacer 164. The metal plug 166 can be electrically insulated from the gate layers 160 by the dielectric spacer 164. In some embodiments, the metal plug 166 can be interchangeably referred to a source line. In some embodiments, the dielectric spacer 164 may be made of dielectric material, such as silicon oxide, silicon nitride (SiN), silicon oxynitride (SiON), silicate, combinations thereof, or other suitable conductive materials. In some embodiments, the metal plug 166 may be made of TiN, TaN, Ti, Ta, Cu, Al, Ag, W, Ir, Ru, Pt, combinations thereof, or other suitable conductive materials.

Reference is made to FIGS. 17A and 17B. An inter-layer dielectric (ILD) layer 170 is formed over the dielectric spacer 164 and the metal plug 166. Subsequently, a plurality of bit lines 172 electrically connected to the bonding pads 156 with an interconnection via 174 formed in the ILD layer 170. Subsequently, after a series of back end of line (BEOL) processes (not shown) are carried out, the IC structure including a plurality of memory cells 162 is formed as shown in FIGS. 17A and 17B. In some embodiments, the memory cells 162 defined by the gate layers 160, the memory layer 150, and the channel layer 152 can be electrically coupled to a decoder, such as a row decoder or a column decoder (not shown), through the bit lines 172. A current coming from the bit lines 172 can flow to the earth by passing through the bonding pad 156, the channel layer 152, the metal plug 166, and the conductive layer 112a, the middle sacrificial layer 112b (that has been replaced with highly doped polysilicon), and the conductive layer 112c. In other words, the current path for performing the read/program operation does not flow through the substrate 100. Therefore, the current path for performing the read/program operation can be decreased, such that the operation resistance and power consumption of the memory device can be reduced. In some embodiments, the ILD layer 170 may be made of silicon oxide, silicon nitride (SiN), silicon oxynitride (SiON), silicate, combinations thereof, or other suitable dielectric materials. In some embodiments, the bit line 172 and/or the interconnection via 174 may be made of TiN, TaN, Ti, Ta, Cu, Al, Ag, W, Ir, Ru, Pt, combinations thereof, or other suitable conductive materials.

Reference is made to FIG. 17C. FIG. 17C illustrates a local enlarged view of IC structure corresponding to FIG. 17B according to some embodiments of the present disclosure. While FIG. 17C shows an embodiment of the IC structure further including a dielectric layer 408 than the semiconductor structure in FIGS. 17A and 17B. In addition, the present disclosure may repeat reference numerals and/or letters in the various examples. This repetition is for the purpose of simplicity and clarity and does not in itself dictate a relationship between the various embodiments and/or configurations discussed. The dielectric layer 408 is similar to the dielectric layer 208 as shown in FIG. 2B, and thus relevant details will not be repeated for brevity.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides an etching barrier layer over the interconnect on the CMOS. The etching barrier layer can act as an etch stop layer or an etch buffer layer during a hole etch process, and thus a consumption in the underlying interconnect can be avoided during the hole etch process.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) structure, comprising:
a plurality of semiconductor devices on a substrate;
an inter-layer dielectric (ILD) structure over the semiconductor devices;
an interconnect in the ILD structure and electrically connected to the semiconductor devices;
a first dielectric layer over the ILD structure;
an etching barrier layer on the first dielectric layer;
a conductive layer on the etching barrier layer; and
a plurality of memory units stacked in a vertical direction over the etching barrier layer.

2. The IC structure of claim 1, wherein the etching barrier layer is made of a different material than the first dielectric layer.

3. The IC structure of claim 1, wherein the etching barrier layer is made of a carbon-containing material.

4. The IC structure of claim 1, wherein the etching barrier layer comprises tungsten, titanium, titanium nitride, or combinations thereof.

5. The IC structure of claim 1, wherein the etching barrier layer is made of metal oxide.

6. The IC structure of claim 1, wherein the etching barrier layer is made of a same material as the conductive layer and has a thicker thickness than the conductive layer.

7. The IC structure of claim 1, further comprising:
a second dielectric layer sandwiched between the etching barrier layer and the conductive layer.

8. The IC structure of claim 7, wherein the second dielectric layer is made of a same material as the first dielectric layer and different than the etching barrier layer.

9. The IC structure of claim 7, wherein the second dielectric layer is made of a different material than the first dielectric layer and the etching barrier layer.

10. The IC structure of claim 1, further comprising:
a source line extending upwardly from the conductive layer and electrically connected to the memory unites, wherein the etching barrier layer further laterally extends between the semiconductor unites and the source line.

11. A method for forming a memory device, comprising:
depositing a first dielectric layer over a plurality of semiconductor device on a substrate;
depositing an etching barrier layer on the first dielectric layer;
forming a conductive layer on the etching barrier layer;
forming a first multi-layered stack on the conductive layer, the first multi-layered stack including first insulating layers stacked in a vertical direction and separated from each other;
performing a first etching process on the first multi-layered stack to form at least one first vertical through opening downwardly extending through the first multi-layered stack and the conductive layer, the etching barrier layer serving as an etch stop layer, wherein one of the at least one first vertical through opening has a greater depth in the etching barrier layer than another one of the at least one first vertical through opening;
forming a memory layer and a channel layer in the at least one first vertical through opening and in contact with the etching barrier layer; and
forming a plurality of first gate layers alternately stacked with the first insulating layers in the vertical direction.

12. The method of claim 11, further comprising:
after performing a first etching process, forming a second multi-layered stack on the first multi-layered stack, the second multi-layered stack including second insulating layers stacked in the vertical direction and separated from each other; and
performing a second etching process on the second multi-layered stack to form at least one second vertical through opening downwardly extending through the second multi-layered stack and overlapping the at least one first vertical through opening, wherein the memory layer and the channel layer further form in the at least one second vertical through opening.

13. The method of claim 12, further comprising:
forming a plurality of second gate layers alternately stacked with the second insulating layers in the vertical direction.

14. The method of claim 11, wherein a ratio of an etching rate of the conductive layer to an etching rate of the etching barrier layer is greater than about 5 during the performing the first etching process.

15. The method of claim 11, wherein the etching barrier layer comprises aluminum oxide, hafnium oxide, or combinations thereof.

16. The method of claim 11, wherein the first dielectric layer is made of silicon oxide.

17. The method of claim 11, further comprising:
forming a second dielectric layer on the etching barrier layer prior to forming the conductive layer.

18. The method of claim 17, wherein the second dielectric layer is made of silicon oxide or silicon nitride.

19. The method of claim 11, wherein the etching barrier layer is made of a metal-containing material.

20. The method of claim 11, wherein the etching barrier layer is made of a carbon-containing material.
